(19) United States
(12) Patent Application Publication
(10) Pub. No.: US 2025/0118571 A1
(43) Pub. Date: Apr. 10, 2025

(54) PLASMA ETCHING METHOD AND METHOD OF MANUFACTURING DISPLAY APPARATUS

(71) Applicant: Samsung Display Co., LTD., Yongin-si (KR)

(72) Inventors: Changho YI, Yongin-si (KR); Sanggab KIM, Yongin-si (KR); Taesung KIM, Yongin-si (KR)

(21) Appl. No.: 18/757,975

(22) Filed: Jun. 28, 2024

(30) Foreign Application Priority Data
Oct. 5, 2023 (KR) 10-2023-0132462

(51) Int. Cl. H01L 21/3213; H01J 37/32

(52) U.S. Cl. CPC H01L 21/32136; H01J 37/32449; H01L 21/32139; H01J 2237/334

(57) ABSTRACT

A plasma etching method reduces redeposition of by-products generated in a process of etching a copper layer. The plasma etching method includes performing a substrate arrangement operation including arranging a substrate including a conductive layer including copper on a mounting portion in a chamber of a plasma etching apparatus, performing a first preliminary etching operation including supplying a first etching gas including a chlorine element into the chamber and applying a first bias voltage to a lower electrode arranged below the substrate, and performing a first etching operation including supplying a second etching gas including a hydrogen element into the chamber and applying a second bias voltage to the lower electrode, wherein the first bias voltage is less than the second bias voltage.

This application claims priority to Korean Patent Application No. 10-2023-0132462, filed on Oct. 5, 2023, and all the benefits accruing therefrom under 35 U.S.C. § 119, the content of which in its entirety is herein incorporated by reference.

### BACKGROUND

### 1. Field

One or more embodiments relate to a plasma etching method and a method of manufacturing a display apparatus, and more particularly, to a plasma etching method capable of reducing redeposition of by-products generated in an etching process for a copper layer, and a method of manufacturing a display apparatus by using the plasma etching method.

### 2. Description of the Related Art

There is an increasing demand for display apparatuses capable of displaying high-resolution images. In some cases, configuring some display apparatuses to display high-resolution images may include reducing the pixel sizes the display apparatuses and reducing the sizes of pixel circuits respectively corresponding to the pixels. In some cases, configuring such display apparatuses may further include decreasing the widths of electrodes and/or lines included in the pixel circuits, and thus, approaches capable of forming the electrodes and the lines by using copper having high conductivity are desired.

Some approaches may use a wet etching process for forming the electrodes and lines by using copper, but in some cases, wet etching may not effectively support precise control of the features (e.g., widths, and the like) of the electrodes and lines. Some other approaches may include forming electrodes and lines by using copper in a plasma etching process.

### SUMMARY

In some plasma etching process according to the related art, when by-products generated in a process of etching a copper layer are discharged in a gas state to the outside of a chamber, the by-products lose energy from coming into contact with an inner surface of the chamber, and the like. Thus, the by-products may be redeposited in a solid state on the inner surface of the chamber.

One or more embodiments include a plasma etching method and a method of manufacturing a display apparatus, which are capable of reducing redeposition of by-products generated in a process of etching a copper layer. However, the described objective is an example and does not limit the scope of the disclosure.

Additional aspects will be set forth in part in the description which follows and, in part, will be apparent from the description, or may be learned by practice of the presented embodiments of the disclosure.

According to one or more embodiments, a plasma etching method includes performing a substrate arrangement operation including arranging a substrate including a conductive layer including copper on a mounting portion in a chamber of a plasma etching apparatus, performing a first preliminary etching operation including supplying a first etching gas including a chlorine element into the chamber and applying a first bias voltage to a lower electrode arranged below the substrate, and performing a first etching operation including supplying a second etching gas including a hydrogen element into the chamber and applying a second bias voltage to the lower electrode, wherein the first bias voltage is less than the second bias voltage.

The conductive layer may include a first portion on which a mask is arranged and a second portion on which the mask is not arranged, the first preliminary etching operation may include forming a converted portion by converting copper included in the second portion into copper chloride, and the first etching operation may include removing the converted portion.

The first preliminary etching operation may further include converting the copper included the second portion into the copper chloride through a reaction corresponding to at least one of following reaction formulas:

Cu(s)+1/2Cl₂(g)→CuCl(s) Reaction Formula 1

CuCl(s)+1/2Cl₂(g)→CuCl₂(s) Reaction Formula 2

Cu(s)+Cl₂(g)→CuCl₂(g) Reaction Formula 3

3Cu(s)+3/2Cl₂(g)→Cu₃Cl₃(g) Reaction Formula 4

The first etching operation may further include removing the converted portion through a reaction corresponding to at least one of following reaction formulas:

3CuCl₂(s)+3H(g)→Cu₃Cl₃(g)+3HCl(g) Reaction Formula 5

CuCl₂(s)+3H(g)→CuH(g)+2HCl(g) Reaction Formula 6

CuCl(s)+2H(g)→CuH(g)+HCl(g) Reaction Formula 7

3CuCl₂(s)+3/2H₂(g)→Cu₃Cl₃(g)+3HCl(g) Reaction Formula 8

The first etching operation may further include stopping the applying of the second bias voltage to the lower electrode in response to a temperature of the mounting portion being greater than 10° C.

The first etching operation may further include stopping the supplying of the second etching gas including the hydrogen element into the chamber in response to the temperature of the mounting portion being greater than 10° C.

The plasma etching method may further include performing a second preliminary etching operation including supplying the first etching gas including the chlorine element into the chamber and applying the first bias voltage to the lower electrode arranged below the substrate, and performing a second etching operation including supplying the second etching gas including the hydrogen element into the chamber and applying the second bias voltage to the lower electrode.

The conductive layer may include a first portion on which a mask is arranged and a second portion on which the mask is not arranged, the second portion may include a first sub-portion adjacent to a surface of the second portion and a second sub-portion excluding the first sub-portion, the first preliminary etching operation may further include forming a first converted sub-portion by converting copper included in the first sub-portion into copper chloride, the first etching operation may further include removing the first converted sub-portion,
the second preliminary etching operation may further include forming a second converted sub-portion by converting copper included in the second sub-portion into copper chloride, and the second etching operation may further include removing the second converted sub-portion.

A thickness of the first sub-portion may be from about 500 Å or greater to less than about 2,000 Å.

According to one or more embodiments, a method of manufacturing a display apparatus includes performing a substrate arrangement operation including arranging a substrate including a conductive layer including copper on a mounting portion in a chamber of a plasma etching apparatus, performing a first preliminary etching operation including supplying a first etching gas including a chlorine element into the chamber and applying a first bias voltage to a lower electrode arranged below the substrate, and performing a first etching operation including supplying a second etching gas including a hydrogen element into the chamber and applying a second bias voltage to the lower electrode, wherein the first bias voltage is less than the second bias voltage.

The conductive layer may include a first portion on which a mask is arranged and a second portion on which the mask is not arranged, the first preliminary etching operation may include forming a converted portion by converting copper included in the second portion into copper chloride, and the first etching operation may include removing the converted portion.

The first preliminary etching operation may further include converting the copper included the second portion into the copper chloride through a reaction corresponding to at least one of following reaction formulas:

Cu(s)+1/2Cl₂(g)→CuCl(s) Reaction Formula 1

CuCl(s)+1/2Cl₂(g)→CuCl₂(s) Reaction Formula 2

Cu(s)+Cl₂(g)→CuCl₂(g) Reaction Formula 3

3Cu(s)+3/2Cl₂(g)→Cu₃Cl₃(g) Reaction Formula 4

The first etching operation may further include removing the converted portion through a reaction corresponding to at least one of following reaction formulas:

3CuCl₂(s)+3H(g)→Cu₃Cl₃(g)+3HCl(g) Reaction Formula

CuCl₂(s)+3H(g)→CuH(g)+2HCl(g) Reaction Formula 6

CuCl(s)+2H(g)→CuH(g)+HCl(g) Reaction Formula 7

3CuCl₂(s)+3/2H₂(g)→Cu₃Cl₃(g)+3HCl(g) Reaction Formula 8

The first portion may correspond to a gate electrode.

The first portion may correspond to at least one of a source electrode and a drain electrode.

The first etching operation may further include stopping the applying of the second bias voltage to the lower electrode in response to a temperature of the mounting portion being greater than 10° C.

The first etching operation may further include stopping the supplying of the second etching gas including the hydrogen element into the chamber in response to the temperature of the mounting portion being greater than 10° C.

The method may further include performing a second preliminary etching operation including supplying the first etching gas including the chlorine element into the chamber and applying the first bias voltage to the lower electrode arranged below the substrate, and performing a second etching operation including supplying the second etching gas including the hydrogen element into the chamber and applying the second bias voltage to the lower electrode.

The conductive layer may include a first portion on which a mask is arranged and a second portion on which the mask is not arranged, the second portion may include a first sub-portion adjacent to a surface of the second portion and a second sub-portion excluding the first sub-portion, the first preliminary etching operation may further include forming a first converted sub-portion by converting copper included in the first sub-portion into copper chloride, the first etching operation may further include removing the first converted sub-portion, the second preliminary etching operation may further include forming a second converted sub-portion by converting copper included in the second sub-portion into copper chloride, and the second etching operation may include removing the second converted sub-portion.

A thickness of the first sub-portion may be from about 500 Å or greater to less than about 2,000 Å.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an example of a plasma etching apparatus using a plasma etching method according to an embodiment;

FIG. 2 is a flowchart of a plasma etching method according to an embodiment;

FIGS. 3 to 5 are views for describing the plasma etching method of FIG. 2;

FIG. 6 is a flowchart of a plasma etching method according to an embodiment;

FIGS. 7 to 11 are views for describing the plasma etching method of FIG. 6; and

FIG. 12 is a schematic cross-sectional view of a display apparatus manufactured according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments supported by the present disclosure are shown by way of example in the drawings and will herein be described in detail. Effects and characteristics of the disclosure and methods of achieving the same will become apparent by referring to the embodiments described in detail below along with the drawings. However, the disclosure is not limited to the embodiments disclosed hereinafter and may be realized in various forms.

It will be understood that although the terms “first,” “second,” and the like may be used herein to describe various components, these components should not be limited by these terms. These components are used to distinguish one component from another and are not to be limited thereto.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

In the present disclosure, the expression “A and/or B” may indicate A, B, or A and B. Also, the expression “at least one of A and B” may indicate A, B, or A and B.

In the present disclosure, when elements, such as, for example, a layer, a film, an area, a plate, and the like are referred to as being “on” another element, the reference may indicate not only a case where the element is “directly on” the other element, but also a case where yet another element is between the element and the other element.

In the present disclosure, it will be understood that when an element, an area, or a layer is referred to as being connected to another element, area, or layer, the element, area, or layer can be directly and/or indirectly connected to the other element, area, or layer. For example, it will be understood in the present disclosure that when an element, an area, or a layer is referred to as being in contact with or being electrically connected to another element, area, or layer, the element, area, or layer can be directly and/or indirectly in contact with or electrically connected to the other element, area, or layer.

In the present disclosure, an x-axis, a y-axis and a z-axis may not be limited to three axes of a rectangular coordinate system and may be interpreted in a broader sense. For example, the x-axis, the y-axis, and the z-axis may be perpendicular to one another, or may represent different directions that are not perpendicular to one another.

In the present disclosure, when a certain embodiment may be implemented differently, a specific process order may be performed differently from the described order. For example, two consecutively described processes may be performed substantially at the same time or performed in an order opposite to the described order.

In the present disclosure, the expression “in a plan view” denotes when an object is downwardly viewed. That is, for example, in the present disclosure, “in a plan view” may denote “when an object is viewed in a direction perpendicular to a substrate S.”

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially the same,” as used herein, means approximately or actually the same (e.g., within a threshold difference amount).

Hereinafter, embodiments of the disclosure will be described in detail by referring to the accompanying drawings. In descriptions with reference to the drawings, the same reference numerals are given to components that are the same or substantially the same and descriptions will not be repeated. For convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings.

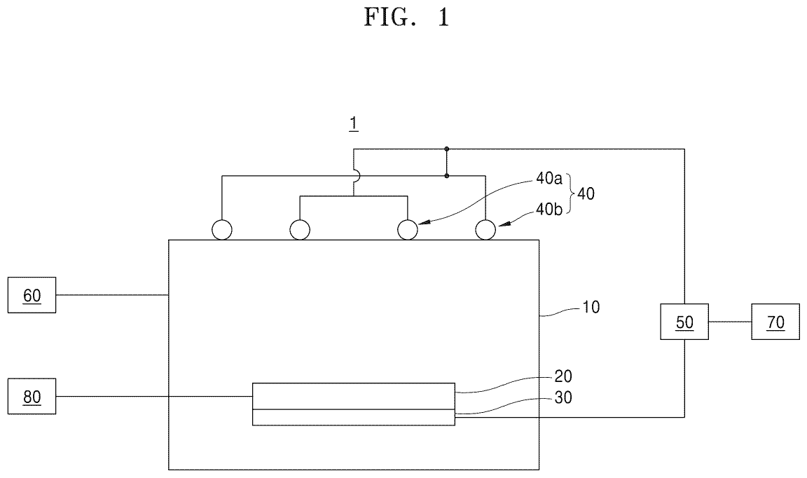

FIG. 1 is a block diagram of an example of a plasma etching apparatus 1 for a plasma etching method according to an embodiment. The plasma etching method according to an embodiment may be performed by the plasma etching apparatus 1.

Referring to FIG. 1, the plasma etching apparatus 1 may include a chamber 10, a mounting portion 20, a lower electrode 30, an upper electrode 40, a power supply portion 50, a gas supply portion 60, and a controller 70. The plasma etching apparatus 1 may further include a cooling portion 80.

The plasma etching apparatus 1 may be, for example, an induced coupled plasma (ICP) etching apparatus. However, embodiments of the present disclosure are not limited thereto. For example, the plasma etching apparatus 1 may be a capacitively coupled plasma (CCP) etching apparatus or a micro-wave type plasma etching apparatus.

A space may be formed inside the chamber 10, and a portion of the space may be open. In some aspects, a gate valve (not shown) may be formed in the open portion of the chamber 10. In this case, for example, according to an operation of the gate valve, the open portion of the chamber 10 may be opened or closed. Accordingly, with respect to a substrate, the chamber 10 may provide a space separate from the outside. That is, for example, the chamber 10 may provide a closed space in order to perform a plasma etching process on the substrate. The chamber 10 may generally have a square pillar shape. However, embodiments of the present disclosure are not limited thereto. For example, the chamber 10 may have a cylindrical shape. The chamber 10 may include a lower wall, an upper wall, and side walls defining the space formed inside the chamber 10 as described herein.

The substrate may include a display substrate, a semiconductor substrate, a glass substrate, or the like. A copper layer which is to be etched to form an electrode and/or a line may be formed on the substrate, and a mask may be formed or arranged on the copper layer. The mask may define a portion of the copper layer, the portion being to be etched. The mask may include a hard mask including metal, silicon oxide, or the like and may be formed by a photoresist. In addition to the copper layer, one or more patterned or non-patterned layers may be formed or arranged on the substrate. The one or more patterned or non-patterned layers may be arbitrary layers appropriate for a certain apparatus (e.g., a display apparatus to be formed in association with one or more plasma etching methods described herein).

The mounting portion 20 may support the substrate. For example, the substrate may be mounted on the mounting portion 20. In some aspects, the mounting portion 20 may be formed as a plate fixed in the chamber 10. Alternatively, the mounting portion 20 may be formed as a shuttle on which the substrate is mounted and which is capable of a linear motion in the chamber 10. The mounting portion 20 may include an electrostatic chuck (not shown) controllable to fix the substrate to the mounting portion 20. The electrostatic chuck may fix the substrate to the mounting portion 20 by using electrostatic adsorptive power.

The lower electrode 30 may be arranged below and/or in the mounting portion 20. FIG. 1 illustrates that the lower electrode 30 is arranged below the mounting portion 20 as an individual element which is separate from the mounting portion 20. However, embodiments of the present disclosure are not limited thereto. For example, the mounting portion 20 may have, inside the mounting portion 20, an element corresponding to the lower electrode 30. In this case, for example, the plasma etching apparatus 1 may not include the lower electrode 30 as an individual element which is separate from the mounting portion 20. That is, for example, the lower electrode 30 may be arranged below the substrate.

The mounting portion 20 may include, inside the mounting portion 20, a circulation channel (not shown) for cooling. The circulation channel may be connected to the cooling portion 80, and thus, a temperature of the mounting portion 20 may be controlled by the cooling portion 80. For example, the cooling portion 80 may supply a refrigerant to the mounting portion 20 in a circulation manner such that the plasma etching apparatus 1 may maintain or obtain a preset temperature at the mounting portion 20.

The upper electrode 40 may be arranged on the chamber 10. The upper electrode 40 may be a high frequency (RF) antenna. The antenna may have a flat coil shape. For example, the upper electrode 40 may include an inner coil 40a and an outer coil 40b. The inner coil 40a and the outer coil 40b may have spiral shapes or concentric circular shapes. The inner coil 40a and the outer coil 40b may generate an inductively coupled plasma in the inner space of the chamber 40. In some aspects, two coils are described for example, but it may be understood that the number and the arrangement of coils and other characteristics of the upper electrode 40 described herein are not limited thereto.

Although not shown, a dielectric window having a disc shape may be arranged between the upper electrode 40 and the chamber 10. The dielectric window may include a dielectric material. For example, the dielectric window may include Al₂O₃. The dielectric window may transmit power from the upper electrode 40 (antenna) into the chamber 10.

The power supply portion 50 may supply bias power and source power to the lower electrode 30 and the upper electrode 40, respectively. For example, the power supply portion 50 may apply the source power to the upper electrode 40 in association with forming a plasma in the chamber 10. The power supply portion 50 may apply the bias power to the lower electrode 30.

The gas supply portion 60 may supply gas into the chamber 10 and may discharge the gas from the chamber 10. For example, the gas supply portion 60 may include a gas supply pipe, a flow amount controller, and a gas supply source. The gas supply portion 60 may supply and discharge various gases into and from the chamber 10 through an upper portion and/or a side surface of the chamber 10. The gas supply portion 60 may provide different gases into the chamber 10 by a desired ratio. In detail, the gas supply portion 60 may store a plurality of gases and may supply the gases into the chamber 10 through the gas supply pipes. The flow amount controller may control a flow amount of the gas supplies introduced into the chamber 10 through the gas supply pipes. The gas supply portion 60 may supply gases used in different processes into the chamber 10. For example, the gas supply portion 60 may supply gases used in a preliminary etching process and gases used in an etching process into the chamber 10. According to an embodiment, the gases may include inert gases.

The controller 70 may control general functions associated with executing features of the plasma etching apparatus 1. For example, the controller 70 may be connected to the power supply portion 50 and may control operations of the power supply portion 50. The controller 70 may include a microcomputer and various interfaces and may control the operations of the power supply portion 50 according to a program and recipe information stored in an external memory or an embedded memory. For example, the controller 70 may execute the program in association with controlling the operations of the power supply portion 50.

In detail, the controller 70 may control the application of the source power to the upper electrode 40. For example, the controller 70 may apply the source power to the upper electrode 40 such that an electromagnetic field induced by the upper electrode 40 is applied to a gas injected into the chamber 10, and the application of the electromagnetic field to the gas may result in a plasma being generated. In some aspects, the controller 70 may control the application of the bias power to the lower electrode 30. For example, the controller 70 apply the bias power to the lower electrode 30 such that a surface of the substrate is of a desired voltage and ion energy distribution and a desired ion flux and etch rate is obtained.

FIG. 1 illustrates the plasma etching apparatus 1 including some elements related to the present embodiments, but is not limited thereto. Thus, it is apparent to one of ordinary skill in the art that the plasma etching apparatus 1 may further include other elements supportive of aspects of the plasma etching apparatus 1 and other general-purpose elements, in addition to the elements illustrated in FIG. 1. For example, the plasma etching apparatus 1 may include or may be connected to various devices configured to control or operate the elements illustrated in FIG. 1. Alternatively, the controller 70 of the plasma etching apparatus 1 may control other elements illustrated in FIG. 1 except for the power supply portion 50. For example, the controller 70 of the plasma etching apparats 1 may control operations of the mounting portion 20, the gas supply portion 60, and/or the cooling portion 80. That is, for example, the illustrated plasma etching apparatus 1 is an example and may be variously modified as recognized by one of ordinary skill in the art.

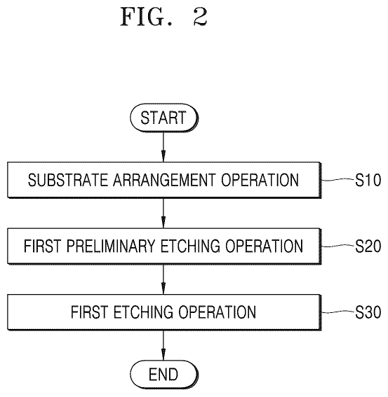

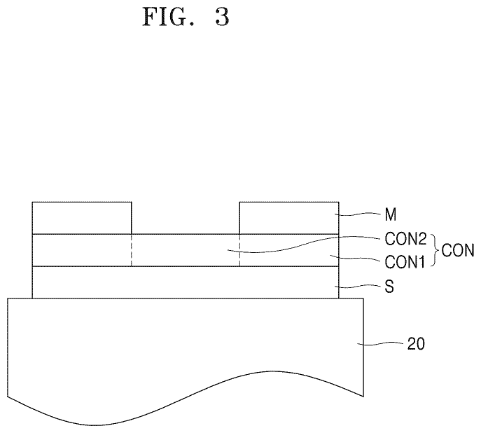

FIG. 2 is a flowchart of a plasma etching method according to an embodiment. FIGS. 3 to 5 are views for describing the plasma etching method of FIG. 2.

Referring to FIG. 2, the plasma etching method according to an embodiment may include a substrate arrangement operation S10, a first preliminary etching operation S20, and a first etching operation S30. For example, the plasma etching method may include performing the substrate arrangement operation S10, the first preliminary etching operation S20, and the first etching operation S30.

Referring to FIG. 3, in the substrate arrangement operation S10, the plasma etching method may include arranging a substrate S on which a conductive layer CON including copper may be formed, on the mounting portion 20 in the chamber 10 of the plasma etching apparatus 1. The substrate S may include a display substrate, a semiconductor substrate, a glass substrate, or the like. The plasma etching method may include forming the conductive layer CON on the substrate S.

The conductive layer CON may be formed on the substrate S through sputtering, for example. That is, for example, the plasma etching method may include depositing the conductive layer CON on the substrate S. In other words, the plasma etching method may include arranging the conductive layer CON on the substrate S. The conductive layer CON may include copper. For example, the conductive layer CON may include a copper layer. That is, for example, the conductive layer CON may include a copper thin layer.

The plasma etching method may include etching conductive layer CON to form an electrode and/or a line. To this end, the plasma etching method may include arranging a mask M on the conductive layer CON. The mask M may include a hard mask including metal, silicon oxide, or the like and may be formed by a photoresist. The mask M may define a portion of the conductive layer CON to be etched.

In other words, the conductive layer CON may include a first portion CON1 and a second portion CON2. The first portion CON1 may be a portion not to be etched, and the second portion CON2 may be a portion to be etched. That is, for example, the mask M may be arranged on the first portion CON1, and the mask M may not be arranged on the second portion CON2. Expressed another way, the mask M may be arranged such that the mask M is on the first portion CON1 but not on the second portion CON2. The plasma etching method may include forming or arranging one or more patterned or non-patterned layers between the substrate S and the conductive layer CON. The one or more patterned or non-patterned layers may be arbitrary layers appropriate for a certain apparatus (e.g., a display apparatus DA to be formed in association with one or more plasma etching methods described herein).

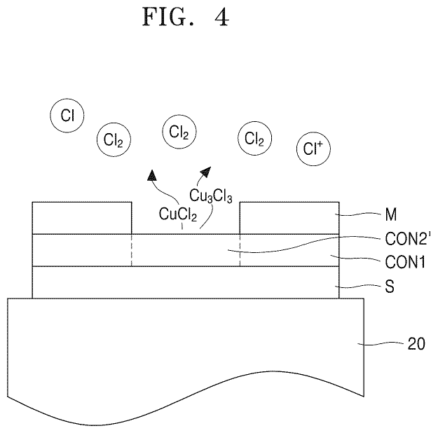

Referring to FIG. 4, in the first preliminary etching operation S20, the plasma etching method may include supplying a first etching gas including chlorine gas into the chamber 40. In the present disclosure, the chlorine gas denotes a gas including a chlorine molecule Cl₂. The chlorine gas includes a chlorine element, and thus, the “first etching gas including the chlorine gas” described herein may be the “first etching gas including the chlorine element.”

A portion of the chlorine gas of the first etching gas may form a chlorine plasma through the upper electrode 40. Thus, copper included in a portion of the conductive layer CON may be converted into copper chloride. For example, the plasma etching method may include converting copper of the second portion CON2, on which the mask M is not arranged, into copper chloride, such as, for example, CuCl, CuCl₂, or Cu₃Cl₃. Accordingly, a second converted portion CON2′ (also referred to herein as a converted portion) including CuCl and/or CuCl₂ may be formed. That is, for example, the plasma etching method may include forming the second converted portion CON2′ by converting the copper of the second portion CON2 into the copper chloride.

In detail, a portion of the chlorine gas of the first etching gas may form a chlorine plasma through the upper electrode 40, and the chlorine plasma may include chlorine positive ions and chlorine radicals. Another portion of the chlorine gas of the first etching gas may be adjacent to a surface of the second portion CON2 or may be adsorbed by the surface of the second portion CON2. The chlorine gas adjacent to the surface of the second portion CON2 or adsorbed by the surface of the second portion CON2 may react with the copper of the second portion CON2, and the chlorine positive ions and the chlorine radicals may increase a rate of this reaction. That is, for example, the first preliminary etching operation S20 may be a reactive ion etch process. Accordingly, for example, the plasma etching method may include converting the copper of the second portion CON2 to the copper chloride.

In general, the plasma etching method may include converting copper into copper chloride by reacting the copper with a chlorine molecule Cl₂ using one or more of Reaction Formula 1 through Reaction Formula 4 described herein.

Cu(s)+1/2Cl₂(g)→CuCl(s) Reaction Formula 1

CuCl(s)+1/2Cl₂(g)→CuCl₂(s) Reaction Formula 2

Cu(s)+Cl₂(g)→CuCl₂(g) Reaction Formula 3

3Cu(s)+3/2Cl₂(g)→Cu₃Cl₃(g) Reaction Formula 4

CuCl generated in Reaction Formula 1 and CuCl₂ generated in Reaction Formula 2 may be in solid states, and CuCl₂ generated in Reaction Formula 3 and Cu₃Cl₃ generated in Reaction Formula 4 may be in gas states. CuCl₂ generated in Reaction Formula 3 and Cu₃Cl₃ generated in Reaction Formula 4 may be discharged to the outside in the gas state. Thus, as the reaction proceeds, the copper of the second portion CON2 may be converted into CuCl generated in Reaction Formula 1 and CuCl₂ generated in Reaction Formula 2. That is, for example, the copper of the second portion CON2 may be converted into the copper chloride. Accordingly, the second converted portion CON2′ including CuCl and/or CuCl₂ may be formed.

The plasma etching method may include applying first bias power in the first preliminary etching operation S20. In detail, in the first preliminary etching operation S20, the plasma etching method may include applying the first bias power to the lower electrode 30. The first bias power applied to the lower electrode 30 in the first preliminary etching operation S20 may be less than second bias power applied to the lower electrode 30 in a second etching operation S50 to be described herein. The effect achieved by the first bias power being less than the second bias power will be described later herein.

According to another embodiment, the first etching gas may further include hydrogen gas. In this case, for example, the hydrogen gas may be included in the first etching gas by a 10 volume percentage (%) or less with respect to the total volume of the first etching gas. In an example in which the first etching gas includes hydrogen gas by greater than the 10 volume % with respect to the total volume of the first etching gas, the amount of chlorine gas included in the first etching gas may be greatly reduced, and thus, the speed at which the copper of the second portion CON2 reacts with the chlorine molecule Cl₂ may be reduced.

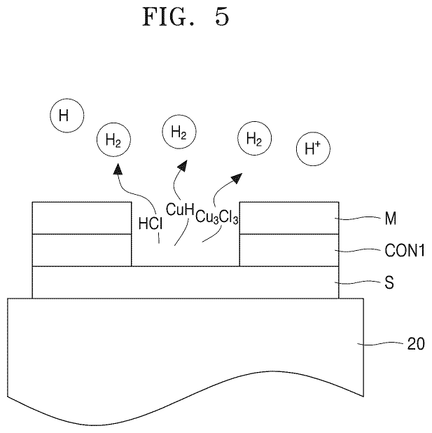

Referring to FIG. 5, in the first etching operation S30, the plasma etching method may include supplying a second etching gas including hydrogen gas into the chamber 10. In the present disclosure, the hydrogen gas denotes a gas including a hydrogen molecule H₂. The hydrogen gas includes a hydrogen element, and thus, the “second etching gas including the hydrogen gas” described herein may be the “second etching gas including the hydrogen element.” In the case of a general plasma etching process, the amount of gas in the chamber 10 may be controlled by simultaneously supplying and discharging the gas into and from the chamber 10. Thus, the plasma etching method may be implemented without providing an additional operation of purging the first etching gas between the first preliminary etching operation S20 and the first etching operation S30. That is, for example, the plasma etching method may include supplying the second etching gas including the hydrogen gas into the chamber 10, and simultaneously, discharging the first etching gas including the chlorine gas from the chamber 10. Accordingly, for example, in the first etching operation S30, the plasma etching method may include filling the chamber 10 with the second etching gas including the hydrogen gas,. However, embodiments of the present disclosure are not limited thereto, and the plasma etching method may include performing an additional operation of discharging (purging) the first etching gas, between the first preliminary etching operation S20 and the first etching operation S30.

A portion of the hydrogen gas of the second etching gas may form a hydrogen plasma through the upper electrode 40. Accordingly, the portion of the conductive layer CON, in which the copper is converted into the copper chloride, in the first preliminary etching operation S20, may be removed. For example, the plasma etching method may include removing the second portion CON2 in which the copper is converted into the copper chloride in the first preliminary etching operation S20. That is, for example, the plasma etching method may include removing the second converted portion CON2′ formed by the conversion of the copper of the second portion CON2 into CuCl and/or CuCl₂ in the first preliminary etching operation S20.

In detail, a portion of the hydrogen gas of the second etching gas may form a hydrogen plasma through the upper electrode 40, and the hydrogen plasma may include hydrogen positive ions and hydrogen radicals. Another portion of the hydrogen gas of the second etching gas may be adjacent to a surface of the second converted portion CON2′ or may be adsorbed by the surface of the second converted portion CON2′. The hydrogen gas adjacent to the surface of the second converted portion CON2′ or adsorbed by the surface of the second converted portion CON2′ may react with CuCl and/or CuCl₂ of the second converted portion CON2′, and the hydrogen positive ions and the hydrogen radicals may increase a rate of the reaction. That is, for example, the first etching operation S30 may be a reactive ion etch process.

In general, the plasma etching method may include removing CuCl or CuCl₂ by reacting the CuCl or CuCl₂ with a hydrogen molecule H2 or monomolecular hydrogen H using one or more of Reaction Formula 5 through Reaction Formula 8 described herein.

3CuCl₂(s)+3H(g)→Cu₃Cl₃(g)+3HCl(g) Reaction Formula 5

CuCl₂(s)+3H(g)→CuH(g)+2HCl(g) Reaction Formula 6

CuCl(s)+2H(g)→CuH(g)+HCl(g) Reaction Formula 7

3CuCl₂(s)+3/2H₂(g)→Cu₃Cl₃(g)+3HCl(g) Reaction Formula 8

Cu₃Cl₃ and HCl generated in Reaction Formula 5 and Reaction Formula 8 may be in gas states, and CuH and HCl generated in Reaction Formula 6 and Reaction Formula 7 may be in gas states. The plasma etching method may include discharging CuH, Cu₃Cl₃, and HCl generated in Reaction Formulas 5, 6, 7, and 8 to the outside of the chamber 10 in the gas states. Thus, the copper chloride of the second converted portion CON2′ may be removed. That is, for example, the plasma etching method may include etching the conductive layer CON based on a pattern of the mask M. In other words, the second portion CON2 may be removed, and the first portion CON1 may remain.

When hydrogen plasma is formed, a dissociation rate by which a hydrogen molecule H₂ is dissociated into monomolecular hydrogen H may not be sufficiently high (e.g., the dissociation rate may be below a threshold value). Thus, in the first etching operation S30, the number of hydrogen molecules H₂ existing in the chamber 10 may be significantly greater than the number of monomolecular hydrogens H existing in the chamber 10, and the reaction of Reaction Formula 8 may be mainly performed in the chamber 10. However, the reaction of Reaction Formula 8 may be an endothermic reaction, and in some embodiments, the plasma etching method may include increasing the rate of the reaction of Reaction Formula 8 according to an additional energy supply.

For the additional energy supply, the plasma etching method may include applying the second bias power in the first etching operation S30, in which the second bias power is greater than first bias power applied in the first preliminary etching operation S20. That is, for example, the plasma etching method may include applying the second bias power to the lower electrode 30 in the first etching operation S30, and the second bias power may be greater than the first bias power. In other words, the first bias power may be less than the second bias power.

That is, for example, the plasma etching method may include applying the relatively decreased bias power (first bias power) to the lower electrode 30 while providing the first etching gas mainly including the chlorine gas into the chamber 10. The plasma etching method may include applying the relatively increased bias power (second bias power) to the lower electrode 30 while providing the second etching gas mainly including the hydrogen gas into the chamber 10. In an example, the first bias power may be 25% of the source power or lower, and the second bias power may be 50% of the source power or higher. That is, for example, when the source power is 2,000 W, the first bias power may be 500 W or lower, and the second bias power may be 1,000 W or higher.

In general, in order to plasma etch a copper layer, a mixed gas mainly including a halogen-based gas such as, for example, fluorine gas or chlorine gas may be used. The mixed gas may further include hydrogen gas, nitrogen gas, helium gas, argon gas, or the like suitable for plasma etching. In an example in which a mixed gas including the chlorine gas is used to plasma etch the copper layer, the chlorine gas may react with copper to form by-products in the form of copper chloride, for example, CuCl, CuCl₂, or Cu₃Cl₃.

CuCl and CuCl₂ from among the by-products are in solid states, and the boiling points of CuCl and CuCl₂ may be approximately 1,000° C. at normal pressure. The boiling points of CuCl and CuCl₂ at 10⁻² to 10⁻⁴ Torr, the pressure in the chamber while the plasma etching process is being performed, may be 250° C. or higher. Thus, CuCl and CuCl₂ may be converted into CuH and Cu₃Cl₃, which are evaporable at room temperature, and may be discharged to the outside of the chamber 10.

When the copper layer is plasma etched, the bias power may have to be applied in order to increase the etch rate. However, when high bias power is applied, the number of chlorine particles having high energy, for example, chlorine positive ions, chlorine radicals, or chlorine molecules Cl₂, may increase. In an example in which the chlorine particles having high energy react with copper, CuCl and CuCl₂ that are generated may be instantly evaporated. However, even when CuCl or CuCl₂ is evaporated, the evaporated CuCl or CuCl₂ may come into contact with an inner surface of the chamber 10, etc. while being discharged to the outside of the chamber 10 and may lose energy, such that the evaporated CuCl or CuCl₂ may be redeposited, in a solid state, on the inner surface of the chamber 10.

When the described redeposition continues, an exhaust condition to maintain low pressure in the chamber 10 may change, and when the redeposition is excessive (e.g., the amount of evaporated CuCl or CuCl₂ redeposited in a solid state exceeds a threshold value), the redeposited CuCl or CuCl₂ may clog a pipe (e.g., a gas supply pipe) included in the gas supply portion 60. For example, the pipe may become stuck or obstructed by the redeposited CuCl or CuCl₂ and accordingly be unable to retain a plasma. Also, in some cases, the by-products redeposited on the substrate may contaminate the substrate and may thus deteriorate the quality or reduce a yield rate of a product. In some other approaches, removing redeposited CuCl and CuCl₂, may include heating the chamber 10 of the plasma etching apparatus to 250° C. or higher. Thus, it may be difficult for other approaches to effectively remove the redeposited CuCl and CuCl₂.

However, with reference to the embodiments described herein, the plasma etching method may include supplying the first etching gas including the chlorine gas into the chamber 10 in the first preliminary etching operation S20, and further, supplying the second etching gas including the hydrogen gas into the chamber 10 in the first etching operation S30. In the first preliminary etching operation S20, the plasma etching method may include applying the first bias power to the lower electrode, in which the first bias power is less than the second bias power that is applied in the first etching operation S30. Thus, for example, by using the first bias power of a lower power level as described herein, there may be no chlorine particles having high energy (e.g., particles having an energy above a threshold energy value), such as, for example, chlorine positive ions, chlorine radicals, or chlorine molecules Cl₂, or the number of chlorine particles having high energy may be small (e.g., below a threshold quantity).

Accordingly, for example, when the chlorine particles react with copper, CuCl and CuCl₂ generated from the reaction may not evaporate. In some cases in which the generated CuCl and CuCl₂ does evaporate, the degree of evaporation may be minimized. Thus, the process of etching the copper layer described herein supports a reduction in the redeposition of the by-products generated due to the etching. That is, for example, according to the present embodiments described herein, applying the relatively decreased bias voltage to the lower electrode 30 in a process in which CuCl and CuCl₂ are generated may minimize the degree of evaporation of CuCl and CuCl₂ and reduce the redeposition of the by-products.

According to another embodiment, the second etching gas may further include a gas different from the hydrogen gas. For example, the second etching gas may further include helium gas or argon gas, which may not react with copper. Accordingly, for example, the plasma etching method may include appropriately adjusting the amount of flow of the second etching gas.

According to another embodiment, the second etching gas may further include chlorine gas. In this case, for example, the chlorine gas may be included in the second etching gas by a 25 volume % or less with respect to the total volume of the second etching gas. In an example in which the second etching gas includes the chlorine gas by greater than 25 volume % with respect to the total volume of the second etching gas, newly generated CuCl and CuCl₂ may be evaporated and redeposited. That is, for example, when CuCl and CuCl₂ are removed by reacting with the hydrogen gas, copper of a portion exposed to the outside may react with a chlorine molecule Cl₂, and CuCl and CuCl₂ generated by the reaction may evaporate and be redeposited.

FIGS. 2 to 5 illustrate that copper of the entire second portion CON2 may be converted into copper chloride in the first preliminary etching operation S20 and the entire second portion CON2 may be removed in the first etching operation S30. However, embodiments of the present disclosure are not limited thereto. For example, when a thickness of the conductive layer CON is sufficiently large (e.g., above a threshold thickness value), copper of a portion of the second portion CON2 may be converted into copper chloride in the first preliminary etching operation S20, and a portion of the second portion CON2 may be removed in the first etching operation S30. In this case, for example, the plasma etching method may include repeatedly performing the preliminary etching operation and the etching operation. That is, for example, the plasma etching method may include repeatedly performing a cycle including one preliminary etching operation and one etching operation. In an example, the plasma etching method may include performing the cycle a plurality of times until one or more target criteria is satisfied (e.g., a target amount of removal of the portion of the second portion CON2, removal of a target amount of copper chloride, or the like).

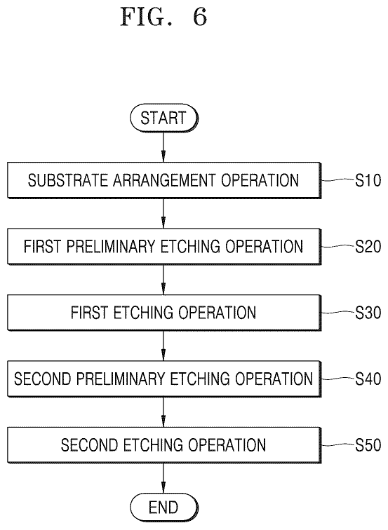

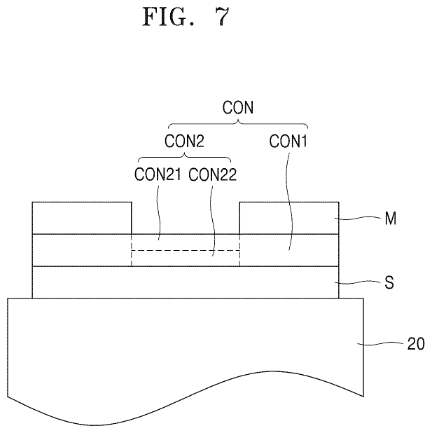

FIG. 6 is a flowchart of a plasma etching method according to an embodiment. FIGS. 7 to 11 are views for describing the plasma etching method of FIG. 6.

The plasma etching method of FIG. 6 includes aspects of the plasma etching method of FIG. 2 described herein, and repeated descriptions of like elements are omitted for brevity. The plasma etching method of FIG. 6 corresponds to a modified embodiment of the plasma etching method of FIG. 2, and thus, the description below is given based on a difference of the plasma etching method of FIG. 6 from the plasma etching method of FIG. 2. Hereinafter, for convenience, aspects that are the same as described herein with reference to FIGS. 1 to 5 are not described.

Referring to FIG. 6, the plasma etching method according to an embodiment may include a substrate arrangement operation S10, the first preliminary etching operation S20, the first etching operation S30, a second preliminary etching operation S40, and a second etching operation S50. For example, the plasma etching method may include performing the substrate arrangement operation S10, the first preliminary etching operation S20, the first etching operation S30, the second preliminary etching operation S40, and the second etching operation S50.

Referring to FIG. 7, in the substrate arrangement operation S10, the plasma etching method may include arranging the substrate S on which the conductive layer CON including copper may be formed on the mounting portion 20 in the chamber 10 of the plasma etching apparatus 1. The conductive portion CON may include the first portion CON1 and the second portion CON2. The first portion CON1 may be a portion not to be etched, and the second portion CON2 may be a portion to be etched. That is, for example, the mask M may be arranged on the first portion CON1, and the mask M may not be arranged on the second portion CON2. Expressed another way, the mask M may be arranged such that the mask M is on the first portion CON1 but not on the second portion CON2.

The second portion CON2 may include a 2nd-1 portion CON21 (also referred to herein as a first sub-portion of the second portion CON2) and a 2nd-2 portion CON22 (also referred to herein as second sub-portion of the second portion CON2). The 2nd-1 portion CON21 may be a portion of the second portion CON2 in a direction of the mask M, and the 2nd-2 portion CON22 may be a portion of the second portion CON2 in a direction opposite to the mask M. That is, for example, the 2nd-1 portion CON21 may be a portion of the second portion CON2 in a direction opposite to the substrate S, and the 2nd-2 portion CON22 may be a portion of the second portion CON2 in a direction of the substrate S. In other words, the 2nd-1 portion CON21 may be a portion of the second portion CON2 which is adjacent to a surface of the second portion CON2, and the 2nd-2 portion CON22 may be a different portion of the second portion CON2. For example, the 2nd-2 portion CON22 may be a portion of the second portion CON2 excluding the 2nd-1 portion CON21).

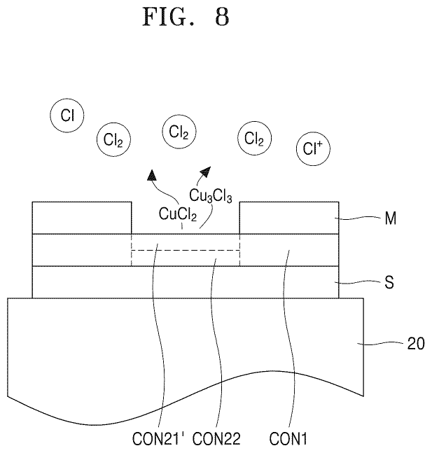

With reference to FIG. 8, in the first preliminary etching operation S20, the plasma etching method may include supplying a first etching gas including chlorine gas into the chamber 10. A portion of the chlorine gas of the first etching gas may form a chlorine plasma through the upper electrode 40. Thus, copper included in a portion of the conductive layer CON may be converted into copper chloride. For example, copper of a portion of the second portion CON2 on which the mask M is not arranged may be converted into copper chloride, for example, CuCl, CuCl₂, or Cu₃Cl₃. Accordingly, a 2nd-1 converted portion CON21′ including CuCl and/or CuCl₂ may be formed. That is, for example, the 2nd-1 converted portion CON21′ may be formed by copper of the 2nd-1 portion CON21 being converted into copper chloride.

In detail, copper of a portion of the second portion CON2, the portion being adjacent to a surface of the second portion CON2, may be converted into copper chloride in the first preliminary etching operation S20. That is, for example, the copper of the 2nd-1 portion CON21 may be converted into the copper chloride in the first preliminary etching operation S20. In other words, the surface of the second portion CON2 may be saturated with the copper chloride in the first preliminary etching operation S20. That is, for example, copper of the surface of the second portion CON2 may be converted into CuCl and/or CuCl₂ in a solid state, and thus, the surface of the second portion CON2 may be saturated with the CuCl and/or CuCl₂.

The techniques described herein may include appropriately adjusting a thickness of the 2nd-1 converted portion CON21′ according to the process efficiency and a degree of generation of by-products during a process. In some embodiments, the thickness of the 2nd-1 converted portion CON21′ may be from 500 Å or greater to less than 2,000 Å. Expressed another way, the thickness of the 2nd-1 converted portion CON21′ may range from 500 Å to 2,000 Å.

For example, if the thickness of the 2nd-1 converted portion CON21′ is less than 500 Å, the number of preliminary etching operations and the number of etching operations associated with removing the entire second portion CON2 may be excessively increased (e.g., above a threshold value). In some cases, a portion of the chlorine gas supplied in the etching operation may remain in the preliminary etching operation, and due to the chlorine gas, CuCl and/or CuCl₂ may be newly generated in the preliminary etching operation. Thus, when the number of preliminary etching operations and the number of etching operations are excessively increased, the amount of CuCl and/or CuCl₂ newly generated in the preliminary etching operations and the etching operations may increase. In an example in which a 2nd-1 thickness T21 is 2,000 Å or greater, the duration associated with converting copper into copper chloride may excessively increase (e.g., to above a threshold duration).

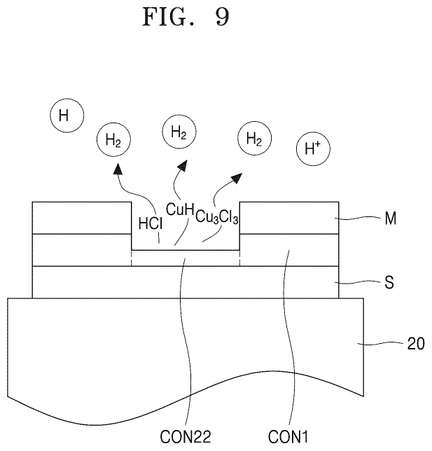

Referring to FIG. 9, in the first etching operation S30, the plasma etching method may include supplying a second etching gas including hydrogen gas into the chamber 10. A portion of the hydrogen gas of the second etching gas may form a hydrogen plasma through the upper electrode 40. Accordingly, a portion of the conductive layer CON, in which copper is converted into copper chloride in the first preliminary etching operation S20, may be removed by the hydrogen plasma. For example, the 2nd-1 portion CON21 in which the copper is converted into the copper chloride in the first preliminary etching operation S20 may be removed. That is, for example, the first etching operation 20 may remove the 2nd-1 converted portion CON21′ formed by the copper of the second portion CON21 being converted into CuCl and/or CuCl₂ in the first preliminary etching operation S20.

In some embodiments, the plasma etching method may include ending the first etching operation S30 when a temperature of the mounting portion 20 is greater than 10° C. In detail, when the temperature of the mounting portion 20 is greater than 10° C., the plasma etching method may include stopping the first etching operation S30, and further, proceeding to apply the second bias voltage to the lower electrode 30. Along with this, the process may include stopping the first etching operation S30, and further, proceeding to supply the second etching gas including the hydrogen gas into the chamber 10.

As described herein, a portion of the chlorine gas supplied in the etching operation may remain in the preliminary etching operation, and due to the chlorine gas, CuCl and/or CuCl₂ may be newly generated in the preliminary etching operation. CuCl and CuCl₂ are nonvolatile materials at room temperature, and at the pressure in the chamber 10 that is from 10⁻² to 10⁻⁴ Torr while the process is being performed in the plasma etching apparatus 1, CuCl and CuCl₂ may evaporate when heat that is 250° C. or higher is applied thereto.

However, due to an additional energy supply according to the second bias voltage applied in the first etching operation S30, a temperature of the substrate S may rise. Accordingly, for example, a portion of CuCl and/or CuCl₂ may be evaporated even without an additional heat supply. Thus, in order to prevent the evaporation and redeposition of newly generated CuCl and/or CuCl₂, the techniques described herein include suppressing a temperature increase in the substrate S. For example, the techniques described herein may include controlling the temperature of the substrate S by controlling a temperature of the mounting portion 20. In detail, the substrate S may be arranged on the mounting portion 20, and thus, the temperature of the substrate S may be the same as or similar to the temperature of the mounting portion 20. Accordingly, the techniques described herein may include controlling the temperature of the substrate S by controlling the temperature of the mounting portion 20.

However, electron heat energy or ion bombardment energy in a plasma exhibits distribution, and thus, the substrate S may be locally heated by particles having higher energy to a sufficient temperature to evaporate CuCl and CuCl₂. In an example in which the temperature of the mounting portion 20 is sufficiently decreased to 10° C. or lower, for example, the temperature of the entire portion of the substrate S may be less than the evaporation points of CuCl and CuCl₂. Thus, the plasma etching method may include discontinuing from applying the second bias voltage when the temperature of the mounting portion 20 is greater than 10° C., which may prevent the evaporation and redeposition of newly generated CuCl and/or CuCl₂. That is, the plasma etching method may include stopping the applying of the second bias voltage based on a temperature of the mounting portion 20 (e.g., when the temperature of the mounting portion 20 is greater than 10° C.).

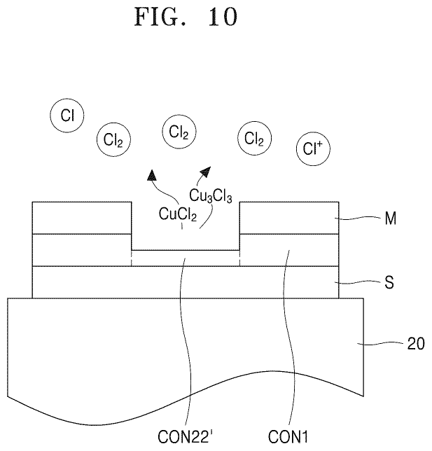

Referring to FIG. 10, in the second preliminary etching operation S40, the plasma etching method may include supplying the first etching gas including the chlorine gas into the chamber 10. As in the first preliminary etching operation S20, a portion of the chlorine gas of the first etching gas may form a chlorine plasma through the upper electrode 40. Thus, copper included in a portion of the conductive layer CON may be converted into copper chloride. For example, copper of the 2nd-2 portion CON22 on which the mask M is not arranged may be converted into a copper chloride, such as, for example, CuCl, CuCl₂, or Cu₃Cl₃. Accordingly, a 2nd-2 converted portion CON22′ including CuCl and/or CuCl₂ may be formed. That is, for example, the 2nd-2 converted portion CON22′ may be formed by the copper of the 2nd-2 portion CON22 being converted into the copper chloride.

In detail, as the 2nd-1 portion CON21 is removed in the first etching operation S30, the 2nd-2 portion CON22 may be adjacent to the surface of the second portion CON2. Thus, the copper of the 2nd-2 portion CON22 adjacent to the surface of the second portion CON2 may be converted into the copper chloride. In other words, the surface of the second portion CON2 may be saturated with the copper chloride in the second preliminary etching operation S40. That is, for example, the copper of the surface of the second portion CON2 may be converted into CuCl and/or CuCl₂ in a solid state, and the surface of the second portion CON2 may be saturated with CuCl and/or CuCl₂.

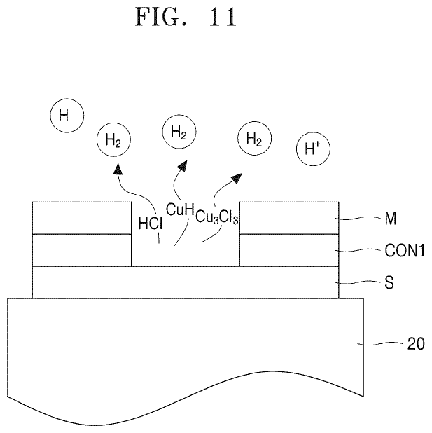

Referring to FIG. 11, in the second etching operation S50, the plasma etching method may include supplying a second etching gas including hydrogen gas into the chamber 10. As in the first etching operation S30, a portion of the hydrogen gas of the second etching gas may form a hydrogen plasma through the upper electrode 40. Accordingly, a portion of the conductive layer CON, in which copper is converted into copper chloride in the second preliminary etching operation S40, may be removed in the second etching operation S50. For example, the 2nd-2 portion CON22 in which the copper is converted into the copper chloride in the second preliminary etching operation S40 may be removed in the second etching operation S50. That is, for example, the 2nd-2 converted portion CON22′ formed by the copper of the 2nd-2 portion CON22 being converted into CuCl and/or CuCl₂ in the second preliminary etching operation S40 may be removed in the second etching operation S50.

FIG. 6 illustrates that the plasma etching method according to an embodiment includes two preliminary etching operations and two etching operations. However, embodiments of the present disclosure are not limited thereto. For example, embodiments of the present disclosure support varying the number of times in which the preliminary etching operations and etching operations of the plasma etching method are performed, based on a thickness of a copper layer to be etched. The plasma etching method described herein may include repeatedly and alternately performing the preliminary etching operation and the etching operation. That is, for example, the plasma etching method may include repeatedly performing a cycle including one preliminary etching operation and one etching operation. In an example, the plasma etching method may include performing the cycle a plurality of times until one or more target criteria is satisfied (e.g., a target etching is achieved, removal of a target amount of copper chloride, or the like). For example, for a cycle including one preliminary etching operation and one etching operation, the plasma etching method may include performing the cycle three, four, five, or more times.

In the descriptions of the flowcharts herein, the operations may be performed in a different order than the order shown, or the operations may be performed in different orders or at different times. Certain operations may also be left out of the flowcharts, one or more operations may be repeated, or other operations may be added to the flowcharts.

Embodiments of the present disclosure support one or more processes (methods, flowcharts) supportive of the features and embodiments described herein. Descriptions that an element “may be arranged,” “may be deposited,” “may be formed,” and the like include processes (methods, flowcharts) and techniques in accordance with example aspects described herein

Hereinafter, a display apparatus, which is one of various electronic devices and electronic components which may be manufactured in accordance with embodiments of the methods described herein, is to be described. The methods described herein may be used to manufacture a display apparatus, such as, for example, an organic light-emitting display apparatus.

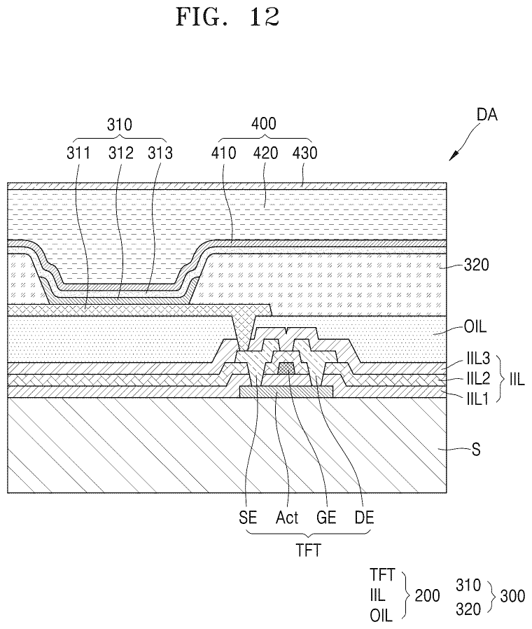

FIG. 12 is a schematic cross-sectional view of a display apparatus DA manufactured according to an embodiment. As recognized by one of ordinary skill in the art, the display apparatus DA may include other various elements in addition to the illustrated elements.

Referring to FIG. 12, the display apparatus DA may include a substrate S. The display apparatus DA may include a transistor and an emission device formed by various layers formed on the substrate S. In detail, the display apparatus DA may include the substrate S, a pixel circuit layer 200, a display element layer 300, and an encapsulation layer 400.

The substrate S may include glass, metal, or polymer resins. The substrate S may have flexible or bendable properties. In this case, for example, the substrate S may include polymer resins, such as, for example, polyethersulfone, polyacrylate, polyetherimide, polyethylene naphthalate, polyethylene terephthalate, polyphenylene sulfide, polyarylate, polyimide, polycarbonate, or cellulose acetate propionate. However, embodiments of the present disclosure support various modifications of the substrate 100. For example, the substrate S may have a multi-layered structure including a barrier layer and two layers including the polymer resins described herein. The barrier layer may be between the two layers and may include an inorganic material (such as, for example, silicon oxide (SiO_{X}), silicon nitride (SiN_{X}), silicon oxynitride (SiO_{X}N_{Y}), or the like).

The pixel circuit layer 200 may be arranged on the substrate S. The pixel circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3.

The semiconductor layer Act may be arranged on the substrate S. The semiconductor layer Act may include polysilicon. Alternatively, the semiconductor layer Act may include amorphous silicon, an oxide semiconductor, or an organic semiconductor. According to an embodiment, the semiconductor layer Act may include a channel area, a source area, and a drain area, in which the source area and the drain area are arranged at different sides of the channel area, respectively.

The gate insulating layer IIL1 may be arranged on the semiconductor layer Act and the substrate S. The gate insulating layer IIL1 may include an inorganic insulating material, such as, for example, SiO_{X}, SiN_{X}, SiO_{X}N_{Y}, Al₂O₃, TiO₂, Ta₂O₅, HfO₂, or ZnO_{X}. ZnO_{X} may include ZnO and/or ZnO₂.

The gate electrode GE may be arranged on the gate insulating layer IIL1. That is, for example, the gate insulating layer IIL1 may be arranged between the semiconductor layer Act and the gate electrode GE, and thus, may provide an insulating property between the semiconductor layer Act and the gate electrode GE. The gate electrode GE may overlap the channel area of the semiconductor layer Act. The gate electrode GE may include a low-resistance metal material. According to an embodiment, the gate electrode GE may include a conductive material including Mo, Al, Cu, Ti, or the like, and may have a single layered or a multi-layered structure including the conductive material. According to an embodiment, the gate electrode GE may have a multi-layered structure of Ti/Cu.

That is, for example, the gate electrode GE may be formed by stacking the conductive material including Mo, Al, Cu, Ti, or the like on the substrate S and patterning the stacked conductive material. In detail, when copper is used as the gate electrode GE, a copper layer may be formed on the substrate S, for example, through sputtering, or the like. That is, for example, the copper layer may be deposited on the substrate S. Next, a mask may be formed or arranged on the copper layer, and the copper layer may be etched by using the plasma etching method according to the embodiments described herein, to form the gate electrode GE, which is a patterned copper layer. That is, for example, the first portion CON1 according to the embodiments described herein with reference to FIGS. 1 to 11 may correspond to the gate electrode GE.

When the copper layer is etched, the temperature of the mounting portion 20 on which the substrate S is mounted may be maintained or decreased such that the temperature is 10° C. or lower, and thus, the temperature of the substrate S may be reduced. Also, hydrogen gas included in the gas provided in the etching operation may react endothermically with CuCl₂, and thus, the temperature of the substrate S may be reduced. Thus, for cases in which the substrate S is a plastic substrate, the substrate S may not be damaged while the copper layer is being plasma etched. In some cases, even if the substrate S is damaged due to the plasma etching of the copper layer, the degree of damage may be minimized.

The first interlayer insulating layer IIL2 may be arranged on the gate electrode GE and the gate insulating layer IIL1. The first interlayer insulating layer IIL2 may include an inorganic insulating material, such as, for example, SiO_{X}, SiN_{X}, SiO_{X}N_{Y}, Al₂O₃, TiO₂, Ta₂O₅, HfO₂, or ZnOₓ.

The source electrode SE and the drain electrode DE may be arranged on the first interlayer insulating layer IIL2. Each of the source electrode SE and the drain electrode DE may be connected to the semiconductor layer Act through a contact hole formed in the gate insulating layer IIL1 and the first interlayer insulating layer IIL2. At least one of the source electrode SE and the drain electrode DE may include a conductive material including Mo, Al, Cu, Ti, or the like and may have a single-layered or a multi-layered structure including the conductive material. According to an embodiment, at least one of the source electrode SE and the drain electrode DE may have a multi-layered structure of Ti/Cu/Ti. In an example in which copper is used as at least one of the source electrode SE and the drain electrode DE, a copper layer may be etched by using the same method as when the copper is used as the gate electrode GE, in order to form the at least one of the source electrode SE and the drain electrode DE. That is, for example, the first portion CON1 according to the embodiments described herein with reference to FIGS. 1 to 11 may correspond to the at least one of the source electrode SE and the drain electrode DE. Thus, the same descriptions regarding these aspects are omitted.

The second interlayer insulating layer IIL3 may be arranged on the source electrode SE, the drain electrode DE, and the first interlayer insulating layer IIL2. The second interlayer insulating layer IIL3 may include an inorganic insulating material, such as, for example, SiO_{X}, SiN_{X}, SiO_{X}N_{Y}, Al₂O₃, TiO₂, Ta₂O₅, HfO₂, or ZnOₓ.

The organic insulating layer OIL may be arranged on the second interlayer insulating layer IIL3. The organic insulating layer OIL may generally planarize an upper portion of the pixel circuit layer 200. The organic insulating layer OIL may include, for example, an organic material, such as, for example, acryl, benzocyclobutene (BCB), or hexamethyldisiloxane (HMDSO). Although the example of FIG. 12 illustrates that the organic insulating layer OIL includes a single layer, embodiments of the present disclosure are not limited thereto, and the organic insulating layer OIL may include multiple layers. As such, embodiments of the present disclosure support modifying the organic insulating layer OIL in various ways.

The display element layer 300 may be arranged on the pixel circuit layer 200. The display element layer 300 may include a display element 310 and a pixel-defining layer 320. The display element 310 may be electrically connected to the transistor TFT. The display element 310 may include an organic light-emitting diode having a pixel electrode 311, an opposite electrode 313, and an intermediate layer arranged between the pixel electrode 311 and the opposite electrode 313. The intermediate layer may include an emission layer. Descriptions that the display element 310 is electrically connected to the transistor TFT may be understood as the pixel electrode 311 of the organic light-emitting diode being electrically connected to the transistor TFT.

The pixel electrode 311 may be in contact with any one of the source electrode SE and the drain electrode DE through a contact hole formed in the second interlayer insulating layer IIL3 and the organic insulating layer OIL such that the pixel electrode 311 is electrically connected to the transistor TFT. The pixel electrode 311 may include a conductive oxide, such as, for example, indium tin oxide (ITO), indium zinc oxide (IZO), ZnO, indium oxide (In₂O₃), indium gallium oxide (IGO), or aluminum zinc oxide (AZO). According to another embodiment, the pixel electrode 311 may include a reflective layer including Ag, Mg, Al, Pt, Pd, Au, Ni, Nd, Ir, Cr, or a compound of any of Ag, Mg, Al, Pt, Pd, Au, Ni, Nd, Ir, or Cr. According to another embodiment, the pixel electrode 311 may further include a layer including ITO, IZO, ZnO or In₂O₃ above/below the reflective layer described herein.

The pixel-defining layer 320 may cover an edge of the pixel electrode 311. The pixel-defining layer 320 may have a pixel-opening portion, and the pixel-opening portion may overlap the pixel electrode 311. The pixel-opening portion may define an emission area of light emitted from the display element 310. The pixel-defining layer 320 may include an organic insulating material and/or an inorganic insulating material. According to some embodiments, the pixel-defining layer 320 may include a light-blocking material.

The intermediate layer 312 may be arranged on the pixel electrode 311 and the pixel-defining layer 320. The intermediate layer 312 may include a low molecular-weight material or a high molecular-weight material. In an example in which the intermediate layer 312 includes a low-molecular weight material, the intermediate layer 312 may have a structure including a stack of any one of or a combination of a hole injection layer (HIL), a hole transport layer (HTL), an emission layer (EML), an electron transport layer (ETL), an electron injection layer (EIL), and other suitable elements for the intermediate layer 312 in accordance with example aspects of the present disclosure, and the intermediate layer 312 may be formed by using a vacuum deposition method. In an example in which the intermediate layer 312 includes a high-molecular weight material, the intermediate layer 312 may have a structure including an HTL and an EML. In some aspects, the HTL may include poly(3,4-ethylenedioxythiophene) (PEDOT) and the EML may include poly-phenylenevinylene (PPV)-based and polyfluorene-based high-molecular weight materials.

The intermediate layer 312 may be formed by a screen printing method, an inkjet printing method, a laser-induced thermal imaging method (LITI), or the like. However, the intermediate layer 312 is not necessarily limited to the examples described herein and may have various structures. In some aspects, the intermediate layer 312 may include a layer integrally formed as a single body throughout a plurality of pixel electrodes 311 or may include layers patterned to respectively correspond to the plurality of pixel electrodes 311.

The opposite electrode 313 may be arranged on the intermediate layer 312 and the pixel-defining layer 320. The opposite electrode 313 may be integrally formed as a single body throughout a plurality of organic light-emitting diodes and may correspond to the plurality of pixel electrodes 311. The opposite electrode 313 may include a transmissive conductive layer including ITO, In₂O₃, or IZO or may also include a transflective layer including a metal, such as, for example, Al or Ag. For example, the opposite electrode 313 may include a transflective layer including Mg or Ag.

In some cases, the display element 310 may be damaged by external moisture or oxygen. The display apparatus DA may include an encapsulation layer 400 which covers and protects the display element 310 from exposure to external moisture or oxygen. Referring to FIG. 12, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include SiO_{X}, SiN_{X}, and/or SiO_{X}N_{Y}. However, according to one or more implementations supported by aspects of the present disclosure, the display apparatus DA may include one or more other layers, such as, for example, a capping layer, arranged between the first inorganic encapsulation layer 410 and the opposite electrode 313. The first inorganic encapsulation layer 410 may be formed along the structures below the first inorganic encapsulation layer 410 (e.g., the capping layer, the opposite electrode 313, and other structures described herein), and thus, with reference to FIG. 12, the first inorganic encapsulation layer 410 may have a non-flat upper surface.

The organic encapsulation layer 420 may cover the first inorganic encapsulation layer 410. In some embodiments, unlike the first inorganic encapsulation layer 410, the organic encapsulation layer 420 may approximately have a flat upper surface. The organic encapsulation layer 420 may include one or more materials selected from the group consisting of polyethyleneterephthalate, polyethylenenaphthalate, polycarbonate, polyimide, polyethylenesulfonate, polyoxymethylene, polyarylate, and hexamethyldisiloxane. The second inorganic encapsulation layer 430 may cover the organic encapsulation layer 420 and may include SiO_{X}, SiN_{X}, and/or SiO_{X}N_{Y}.

In accordance with aspects of the multi-layered structure illustrated at FIG. 12, the encapsulation layer 400 includes the first inorganic encapsulation layer 410, the organic encapsulation layer 420, and the second inorganic encapsulation layer 430. In some aspects, for cases in which cracks occur in the encapsulation layer 400 due to the multi-layered structure, the cracks may not connect between the first inorganic encapsulation layer 410 and the organic encapsulation layer 420 or between the organic encapsulation layer 420 and the second inorganic encapsulation layer 430. Accordingly, aspects of the display apparatus DA may prevent or minimize the formation of paths due to cracking, thereby preventing or minimizing any penetration of external moisture or oxygen into the display apparatus DA.

According to an embodiment as described herein, a plasma etching method and a method of manufacturing a display apparatus, which are capable of reducing redeposition of by-products generated in a process of etching a copper layer, may be realized. However, the scope of the disclosure is not limited to the effects as described herein.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A plasma etching method comprising:
performing a substrate arrangement operation comprising arranging a substrate including a conductive layer including copper on a mounting portion in a chamber of a plasma etching apparatus;
performing a first preliminary etching operation comprising supplying a first etching gas including a chlorine element into the chamber and applying a first bias voltage to a lower electrode arranged below the substrate; and
performing a first etching operation comprising supplying a second etching gas including a hydrogen element into the chamber and applying a second bias voltage to the lower electrode,
wherein the first bias voltage is less than the second bias voltage.

2. The plasma etching method of claim 1, wherein:
the conductive layer includes a first portion on which a mask is arranged and a second portion on which the mask is not arranged,
the first preliminary etching operation comprises forming a converted portion by converting copper included in the second portion into copper chloride, and
the first etching operation includes removing the converted portion.

3. The plasma etching method of claim 2, wherein the first preliminary etching operation further comprises converting the copper included the second portion into the copper chloride through a reaction corresponding to at least one of following reaction formulas:
Cu(s)+1/2Cl₂(g)→CuCl(s) Reaction Formula 1
CuCl(s)+1/2Cl₂(g)→CuCl₂(s) Reaction Formula 2
Cu(s)+Cl₂(g)→CuCl₂(g) Reaction Formula 3
3Cu(s)+3/2Cl₂(g)→Cu₃Cl₃(g) Reaction Formula 4

4. The plasma etching method of claim 2, wherein the first etching operation further comprises removing the converted portion through a reaction corresponding to at least one of following reaction formulas:
3CuCl₂(s)+3H(g)→Cu₃Cl₃(g)+3HCl(g) Reaction Formula 5
CuCl₂(s)+3H(g)→CuH(g)+2HCl(g) Reaction Formula 6
CuCl(s)+2H(g)→CuH(g)+HCl(g) Reaction Formula 7
3CuCl₂(s)+3/2H₂(g)→Cu₃Cl₃(g)+3HCl(g) Reaction Formula 8

5. The plasma etching method of claim 1, wherein the first etching operation includes stopping the applying of the second bias voltage to the lower electrode in response to a temperature of the mounting portion being greater than 10° C.

6. The plasma etching method of claim 1, wherein the first etching operation further includes stopping the supplying of the second etching gas including the hydrogen element into the chamber in response to a temperature of the mounting portion being greater than 10° C.

7. The plasma etching method of claim 1, further comprising:
performing a second preliminary etching operation comprising supplying the first etching gas including the chlorine element into the chamber and applying the first bias voltage to the lower electrode arranged below the substrate; and
performing a second etching operation comprising supplying the second etching gas including the hydrogen element into the chamber and applying the second bias voltage to the lower electrode.

8. The plasma etching method of claim 7, wherein:
the conductive layer includes a first portion on which a mask is arranged and a second portion on which the mask is not arranged,
the second portion includes a first sub-portion adjacent to a surface of the second portion and a second sub-portion excluding the first sub-portion,
the first preliminary etching operation further includes forming a first converted sub-portion by converting copper included in the first sub-portion into copper chloride,
the first etching operation further comprises removing the first converted sub-portion,
the second preliminary etching operation further includes forming a second converted sub-portion by converting copper included in the second sub-portion into copper chloride, and
the second etching operation further includes removing the second converted sub-portion.

9. The plasma etching method of claim 8, wherein a thickness of the first sub-portion is from about 500 Å or greater to less than about 2,000 Å.

10. A method of manufacturing a display apparatus, the method comprising:
performing a substrate arrangement operation comprising arranging a substrate including a conductive layer including copper on a mounting portion in a chamber of a plasma etching apparatus;
performing a first preliminary etching operation comprising supplying a first etching gas including a chlorine element into the chamber and applying a first bias voltage to a lower electrode arranged below the substrate; and
performing a first etching operation comprising supplying a second etching gas including a hydrogen element into the chamber and applying a second bias voltage to the lower electrode,
wherein the first bias voltage is less than the second bias voltage.

11. The method of claim 10, wherein:
the conductive layer includes a first portion on which a mask is arranged and a second portion on which the mask is not arranged,
the first preliminary etching operation further comprises forming a converted portion by converting copper included in the second portion into copper chloride, and
the first etching operation further includes removing the converted portion.

12. The method of claim 11, wherein the first preliminary etching operation further comprises converting the copper included the second portion into the copper chloride through a reaction corresponding to at least one of following reaction formulas:
Cu(s)+1/2Cl₂(g)→CuCl(s) Reaction Formula 1
CuCl(s)+1/2Cl₂(g)→CuCl₂(s) Reaction Formula 2
Cu(s)+Cl₂(g)→CuCl₂(g) Reaction Formula 3
3Cu(s)+3/2Cl₂(g)→Cu₃Cl₃(g) Reaction Formula 4

13. The method of claim 11, wherein the first etching operation further comprises removing the converted portion through a reaction corresponding to at least one of following reaction formulas:
3CuCl₂(s)+3H(g)→Cu₃Cl₃(g)+3HCl(g) Reaction Formula 5
CuCl₂(s)+3H(g)→CuH(g)+2HCl(g) Reaction Formula 6
CuCl(s)+2H(g)→CuH(g)+HCl(g) Reaction Formula 7
3CuCl₂(s)+3/2H₂(g)→Cu₃Cl₃(g)+3HCl(g) Reaction Formula 8

14. The method of claim 11, wherein the first portion corresponds to a gate electrode.

15. The method of claim 11, wherein the first portion corresponds to at least one of a source electrode and a drain electrode.

16. The method of claim 10, wherein the first etching operation further includes stopping the applying of the second bias voltage to the lower electrode in response to a temperature of the mounting portion being greater than 10° C.

17. The method of claim 10, wherein the first etching operation further includes stopping the supplying of the second etching gas including the hydrogen element into the chamber in response to a temperature of the mounting portion being greater than 10° C.

18. The method of claim 10, further comprising:
performing a second preliminary etching operation comprising supplying the first etching gas including the chlorine element into the chamber and applying the first bias voltage to the lower electrode arranged below the substrate; and
performing a second etching operation comprising supplying the second etching gas including the hydrogen element into the chamber and applying the second bias voltage to the lower electrode.

19. The method of claim 18, wherein:
the conductive layer includes a first portion on which a mask is arranged and a second portion on which the mask is not arranged,
the second portion includes a first sub-portion adjacent to a surface of the second portion and a second sub-portion excluding the first sub-portion,
the first preliminary etching operation further includes forming a first converted sub-portion by converting copper included in the first sub-portion into copper chloride,
the first etching operation further includes removing the first converted sub-portion,
the second preliminary etching operation further includes forming a second converted sub-portion by converting copper included in the second sub-portion into copper chloride, and
the second etching operation further includes removing the second converted sub-portion.

20. The method of claim 19, wherein a thickness of the first sub-portion is from about 500 Å or greater to less than about 2,000 Å.
